(19) United States
(12) Patent Application Publication
(10) Pub. No.: US 2025/0145761 A1
(43) Pub. Date: May 8, 2025

(54) REINFORCING RESIN COMPOSITION AND MOUNTED STRUCTURE

(71) Applicant: Panasonic Intellectual Property Management Co., Ltd., Osaka (JP)

(72) Inventor: SHOHEI SANADA, Hyogo (JP)

(21) Appl. No.: 18/911,292

(22) Filed: Oct. 10, 2024

(30) Foreign Application Priority Data
Nov. 6, 2023 (JP) 2023-189516

(51) Int. Cl. C08G 59/50; C08G 59/08; C08G 59/24; C09D 163/04; H01L 23/00

(52) U.S. Cl. CPC C08G 59/504; C08G 59/08; C08G 59/245; C08G 59/5033; C09D 163/04; H01L 24/10; H01L 24/16; H01L 2224/10125; H01L 2224/10155; H01L 2224/16227

(57) ABSTRACT

A reinforcing resin composition includes: an epoxy compound (A); and an amine compound (B) including at least one selected from the group consisting of a compound (B1) represented by a formula (1), a compound (B2) represented by a formula (2), a compound (B3) represented by a formula (3), a compound (B4) represented by a formula (4), and a compound (B5) represented by a formula (5).

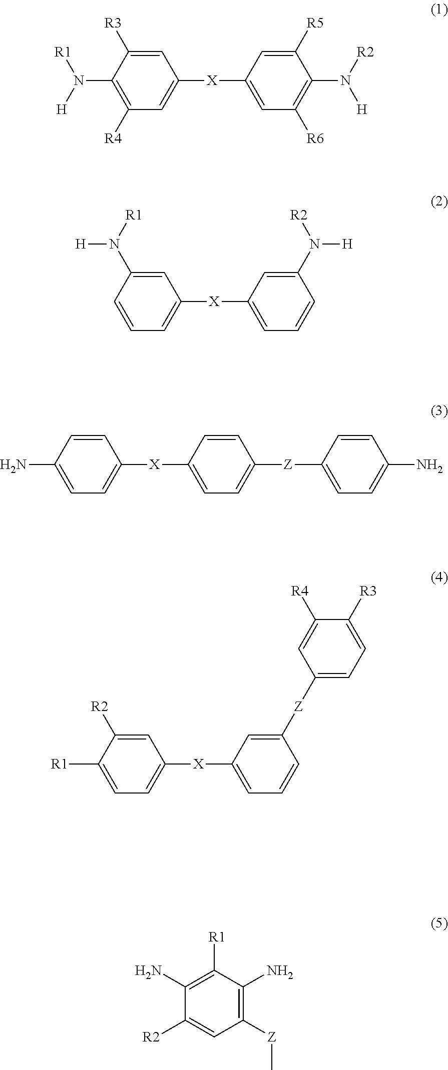

### BACKGROUND

### 1. Technical Field

The present disclosure relates to a reinforcing resin composition and a mounted structure, and more particularly to a reinforcing resin composition containing an epoxy compound, and a mounted structure including a reinforcing part including a cured product of the reinforcing resin composition.

### 2. Description of the Related Art

Unexamined Japanese Patent Publication No. 2020-025973 discloses a flux composition containing 20 wt % or more and 50 wt % or less of an epoxy compound, 15 wt % or more and 45 wt % or less of diallyl bisphenol A, and 1 wt % or more and 30 wt % or less of an organic acid, a solder junction using the flux composition, and a solder joining method using the flux composition.

### SUMMARY

In an embodiment of the present disclosure, a reinforcing resin composition includes: an epoxy compound (A); and an amine compound (B) including at least one selected from the group consisting of a compound (B1) represented by a following formula (1), a compound (B2) represented by a following formula (2), a compound (B3) represented by a following formula (3), a compound (B4) represented by a following formula (4), and a compound (B5) represented by a following formula (5):

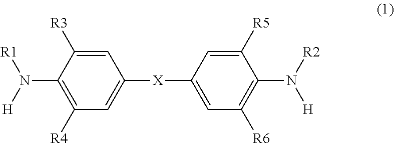

in the formula (1), R1 and R2 each independently represent a hydrogen atom or an alkyl group having 1 to 5 carbon atoms, R3 to R6 each independently represent a hydrogen atom or an alkyl group having 1 to 3 carbon atoms, and X represents —CH₂—, an oxygen atom, —SO₂—, or —C(CF₃)₂—;

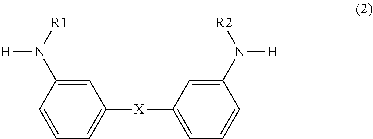

in the formula (2), R1 and R2 each independently represent a hydrogen atom or an alkyl group having 1 to 5 carbon atoms, and X represents —C(CH₃)₂— or an oxygen atom;

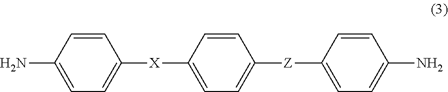

in the formula (3), X represents —C(CH₃)₂— or an oxygen atom, and Z represents —C(CH₃)₂— or an oxygen atom;

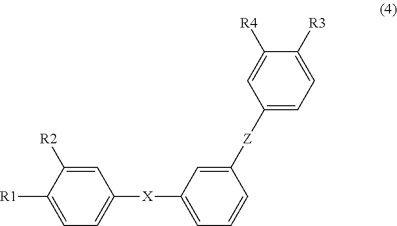

in the formula (4), one of R1 and R2 represents —NH₂ and the other of R1 and R2 represents a hydrogen atom, one of R3 and R4 represents —NH₂ and the other of R3 and R4 represents a hydrogen atom, X represents —C(CH₃)₂— or an oxygen atom, and Z represents —C(CH₃)₂— or an oxygen atom; and

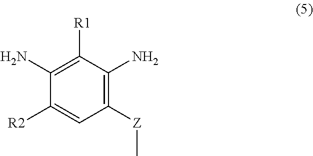

in the formula (5), R1 represents a methyl group or an ethyl group, R2 represents a methyl group, an ethyl group, or —SCH₃, and Z represents —CH₂— or a sulfur atom.

In an embodiment of the present disclosure, a mounted structure includes: a base material including a first conductor; a mounted component having a second conductor; a solder bump disposed between the first conductor and the second conductor, the solder bump electrically connecting the first conductor to the second conductor; and a reinforcing part including a cured product of the reinforcing resin composition. The reinforcing part covers at least one of a joint between the first conductor and the solder bump or a joint between the second conductor and the solder bump.

According to an embodiment of the present disclosure, a reinforcing resin composition capable of improving the heat cycle resistance of a cured product, and a mounted structure including a reinforcing part including a cured product of the reinforcing resin composition can be provided.

### BRIEF DESCRIPTION OF THE DRAWINGS

FIG. 1 is a schematic cross-sectional view of a mounted structure according to the exemplary embodiment of the present disclosure;

FIG. 2 is a schematic cross-sectional view of a mounted structure according to the first modification of the present disclosure; and

FIG. 3 is a schematic cross-sectional view of a mounted structure according to the second modification of the present disclosure.

### DETAILED DESCRIPTIONS OF EMBODIMENTS

When an electronic component and a substrate or the like are mounted by soldering, the junction of both may be reinforced by a reinforcing part including a cured product of a resin composition such as a flux composition (see Unexamined Japanese Patent Publication No. 2020-025973).

Due to the increasing demand for heat resistance and heat cycle resistance of electronic components and the like, it is necessary to improve the heat cycle resistance of the reinforcing part.

According to the present disclosure, a reinforcing resin composition capable of improving the heat cycle resistance of a cured product, and a mounted structure including a reinforcing part including a cured product of the reinforcing resin composition can be provided.

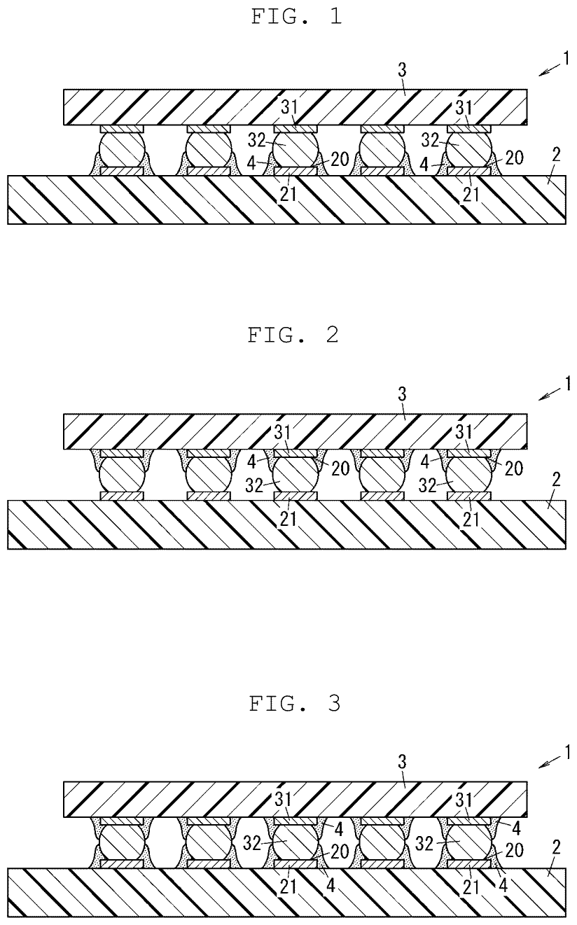

The exemplary embodiments and modifications will be described with reference to FIG. 1 to FIG. 3. However, the exemplary embodiments and the modifications are merely a part of various exemplary embodiments of the present disclosure. In addition, the exemplary embodiments and the modifications can be variously changed depending on design and the like as long as an object of the present disclosure can be achieved. The configuration of the embodiment and the configuration of the modification can be appropriately combined, and the configurations of the modifications can be appropriately combined. Hereinafter, the drawings for reference are schematic drawings, and dimensional ratios of the components in the drawings do not necessarily reflect actual dimensional ratios. Hereinafter, mechanisms relating to action and effect may be described, but all the mechanisms are analogized, and the present disclosure is not limited to the description of the mechanisms.

### 1. Reinforcing Resin Composition

In the exemplary embodiment, the reinforcing resin composition (hereinafter, also referred to as composition (X)) includes an epoxy compound (A) and a specific amine compound (B). Thus, according to the exemplary embodiment, the cured product of the composition (X) can have a glass transition temperature, and the heat resistance of the cured product is enhanced. Hence, the cured product and mounted structure 1 including reinforcing part 4 including the cured product can improve heat cycle resistance.

The composition (X) will be described in more detail.

The epoxy compound (A) is a compound having an epoxy group. The epoxy compound (A) may contain a monomer, and may contain an oligomer. The epoxy compound (A) can impart thermosetting properties to the composition (X). The epoxy compound (A) preferably contains a compound having two or more epoxy groups in one molecule.

The epoxy compound (A) is preferably liquid at normal temperature. In that case, in the composition (X), the epoxy compound (A) and other components can be mixed well. Note that being liquid at normal temperature means having fluidity under atmospheric pressure and in a state where the ambient temperature is 5° C. or more and 28° C. or less (particularly around 20° C.). The epoxy compound (A) may contain only a component that is liquid at normal temperature, or may contain a component that is liquid at normal temperature and a component that is not liquid at normal temperature. Optionally, when the epoxy compound (A) is not liquid at normal temperature, the epoxy compound (A) is compatible with a reactive diluent, a solvent, or the like in the composition (X), and thereby the composition (X) is liquid.

A proportion of the epoxy compound (A) is preferably 48 mass % or more and 85 mass % or less in the solid content of the composition (X). In this case, the composition (X) can have good fluidity, and the composition (X) is easily applied to the joint between the conductor and the solder bump. The proportion is more preferably 49 mass % or more. The proportion is more preferably 80 mass % or less. Note that the solid content is the component other than the component that volatilizes in the process of producing a cured product (solvent or the like) out of the components in the composition (X), in other words, the component that can constitute a cured product.

The epoxy compound (A) preferably includes an epoxy compound (A1) including at least one selected from the group consisting of a naphthalene epoxy resin, a biphenyl aralkyl epoxy resin, a trisphenol methane epoxy resin, a biphenyl epoxy resin, and a dicyclopentadiene epoxy resin. In this case, the glass transition temperature of the cured product can be further increased. This is presumably because the epoxy compound (A1) has a highly rigid structure.

Specifically, it is presumed that each of a naphthalene epoxy resin, a biphenyl aralkyl epoxy resin, a trisphenol methane epoxy resin, a biphenyl epoxy resin, and a dicyclopentadiene epoxy resin, having two or more cyclic structures in one molecule, is restricted in molecular chain movement, and thereby the cured product thereof has a high glass transition point.

The naphthalene epoxy resin is an epoxy compound having one or more naphthalene skeletons in one molecule. The naphthalene epoxy resin has a naphthalene skeleton, which has rigidity and hydrophobicity. Thereby the cured product of the composition (X) can have an improved glass transition temperature.

The biphenyl aralkyl epoxy resin is an epoxy compound having one or more aralkyl skeletons having a biphenyl group in one molecule. The biphenyl aralkyl epoxy resin has a rigid biphenyl group in the aralkyl skeleton. Thereby the cured product of the composition (X) can have an improved glass transition temperature.

The trisphenol methane epoxy resin is an epoxy compound having three phenylmethane skeleton epoxy groups in one molecule. The trisphenol methane epoxy resin has a high functional group (epoxy group) density. Thereby the cured product of the composition (X) can have an improved glass transition temperature.

The dicyclopentadiene epoxy resin is an epoxy compound having one or more dicyclopentadiene skeletons in one molecule. The dicyclopentadiene epoxy resin has a rigid dicyclopentadiene skeleton. Thereby the cured product of the composition (X) can have an improved glass transition temperature.

The epoxy group equivalent of the epoxy compound (A1) is preferably 100 or more and 500 or less.

The naphthalene epoxy resin includes, for example, at least one selected from the group consisting of a compound represented by a following formula (11), a compound represented by a following formula (12), a compound represented by a following formula (13), a compound represented by a following formula (14), a compound represented by a following formula (15), and a compound represented by a following formula (16). Examples of the compound represented by the formula (11) include HP-4032D (semi-solid), which is manufactured by DIC Corporation. Examples of the compound represented by the formula (12) include HP-4700 (softening point: 85° C. to 95° C.) and HP-4710 (softening point: 85° C. to 105° C.), each of which is manufactured by DIC Corporation. Examples of the compound represented by the formula (13) include EXA-4750 (softening point: 80° C.), which is manufactured by DIC Corporation. Examples of the compound represented by the formula (14) include HP-4770 (softening point: 67° C. to 77° C.), which is manufactured by DIC Corporation. Examples of a mixture of the compound represented by the formula (15) and the compound represented by the formula (16) include HP-6000 (softening point: 65° C. to 85° C.) and HP-6000L (softening point: 59° C.), each of which is manufactured by DIC Corporation.

The trisphenol methane epoxy resin includes, for example, at least one selected from the group consisting of a compound represented by a following formula (17), a compound represented by a following formula (18), and a compound represented by a following formula (19). Examples of the compound represented by the formula (17) include HP-7241 (softening point: 66° C.), which is manufactured by DIC Corporation. Examples of the compound represented by the formula (18) include HP-7250 (semi-solid), which is manufactured by DIC Corporation. Examples of the compound represented by the formula (19) include EPPN-501H (softening point: 51° C. to 57° C.), EPPN-501HY (softening point: 57° C. to 63° C.), and EPPN-502H (softening point: 60° C. to 72° C.), each of which is manufactured by Nippon Kayaku Co., Ltd.

The biphenyl aralkyl epoxy resin includes, for example, a compound represented by a formula (20). Examples of the compound represented by the formula (20) include NC-3000 (softening point: 53° C. to 63° C.), NC-3000L (softening point: 45° C. to 60° C.), NC-3000-H (softening point: 65° C. to 75° C.), and NC-3100 (softening point: 90° C. to 103° C.), each of which is manufactured by Nippon Kayaku Co., Ltd.

The biphenyl epoxy resin includes, for example, a compound represented by a formula (21). Examples of the compound represented by the formula (21) include YH4000 (softening point: 105° C.) and YX4000H (softening point: 105° C.), each of which is manufactured by Mitsubishi Chemical Corporation.

The dicyclopentadiene epoxy resin includes, for example, a compound represented by a formula (22). Examples of the compound represented by the formula (22) include HP-7200 (softening point: 56° C. to 66° C.), HP-7200L (softening point: 50° C. to 60° C.), HP-7200H (softening point: 78° C. to 88° C.), HP-7200HH (softening point: 88° C. to 98° C.), and HP-7200HHH (softening point: 100° C. to 110° C.), each of which is manufactured by DIC Corporation, and XD-1000 (softening point: 68° C. to 78° C.), which is manufactured by Nippon Kayaku Co., Ltd.

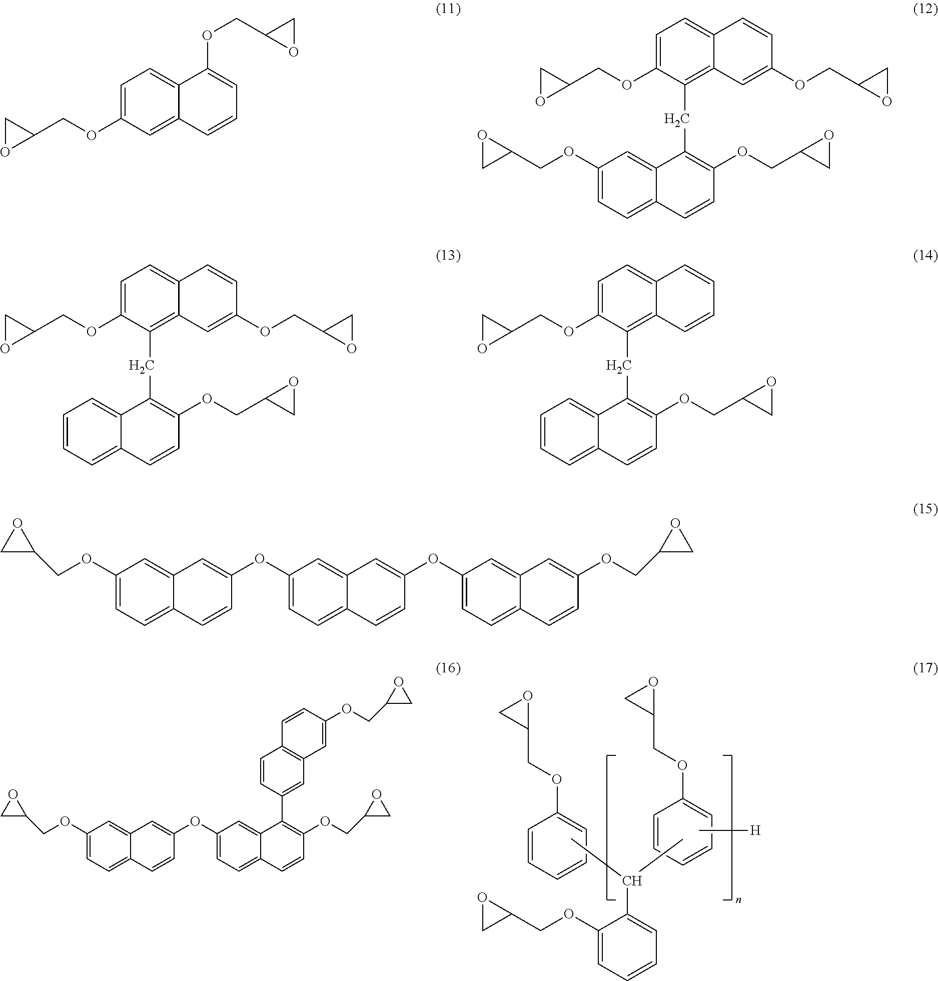

In the formula (17), “n” represents an integer in a range of 1 to 10.

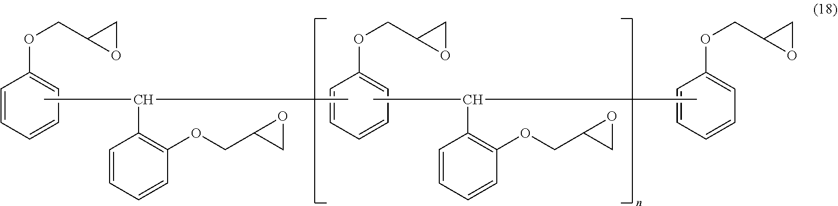

In the formula (18), “n” represents an integer in a range of 1 to 10.

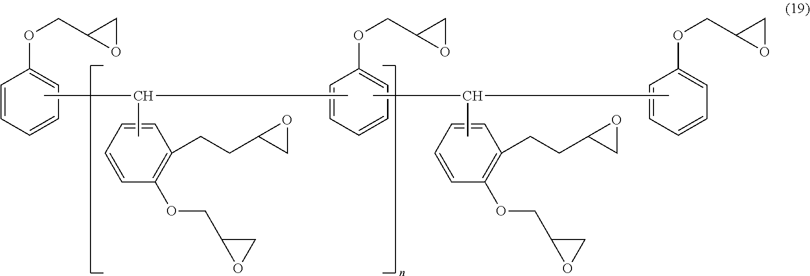

In the formula (19), “n” represents an integer in a range of 1 to 10.

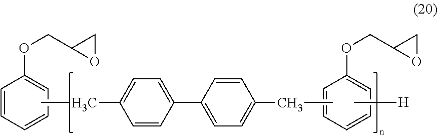

In the formula (20), “n” represents an integer in a range of to 10.

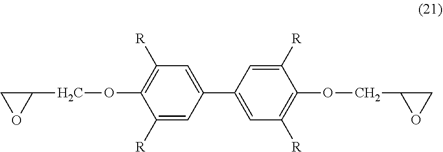

In the formula (21), R represents a methyl group.

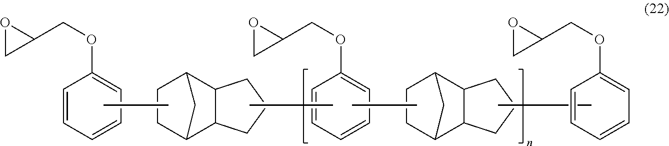

In the formula (22), “n” represents an integer in a range of 1 to 10.

A proportion of the epoxy compound (A1) is preferably 16 mass % or more and 35 mass % or less in the solid content of the composition (X). When the proportion is 16 mass % or more, the glass transition temperature of the cured product can be further increased. The proportion is more preferable 18 mass % or more. When the proportion is 35 mass % or less, there is an advantage that the fluidity of the composition (X) is easily secured. The proportion is more preferably 32 mass % or less.

The epoxy compound (A) may include a compound other than the epoxy compound (A1) (hereinafter, referred to as epoxy compound (A2)).

When the epoxy compound (A) includes the epoxy compound (A1), the epoxy compound (A1) is often semi-solid or solid. Therefore, preferably, the epoxy compound (A) includes the epoxy compound (A2) in addition to the epoxy compound (A1), and thereby the epoxy compound (A) is liquid as a whole. In this case, the composition (X) can have better flowability.

When the epoxy compound (A) includes the epoxy compound (A1) and the epoxy compound (A2), the proportion of the epoxy compound (A1) is preferably 30 mass % or more and 40 mass % or less in the epoxy compound (A).

The epoxy compound (A2) contains, for example, a compound that is liquid and has lower rigidity than the epoxy compound (A1). The epoxy compound (A2) may include, for example, at least one selected from the group consisting of a glycidyl ether epoxy resin, a glycidyl amine epoxy resin, a glycidyl ester epoxy resin, an olefin oxidized (alicyclic) epoxy compound, bisphenol epoxy resins such as a bisphenol A epoxy resin and a bisphenol F epoxy resin, hydrogenated bisphenol epoxy resins such as a hydrogenated bisphenol A epoxy resin and a hydrogenated bisphenol F epoxy resin, an alicyclic epoxy compound, a phenol novolac epoxy resin, a cresol novolac epoxy resin, an aliphatic epoxy compound, and a triglycidyl isocyanurate.

The epoxy compound (A2) more preferably includes at least one selected from the group consisting of a bisphenol A epoxy resin, a bisphenol F epoxy resin, a hydrogenated bisphenol A epoxy resin, and a hydrogenated bisphenol F epoxy resin. In this case, the viscosity of the composition (X) can be reduced, and the physical properties of the cured product of the composition (X) can be improved.

As described above, the composition (X) includes a specific amine compound (B). The amine compound (B) includes at least one selected from the group consisting of a compound (B1) represented by a following formula (1), a compound (B2) represented by a following formula (2), a compound (B3) represented by a following formula (3), a compound (B4) represented by a following formula (4), and a compound (B5) represented by a following formula (5):

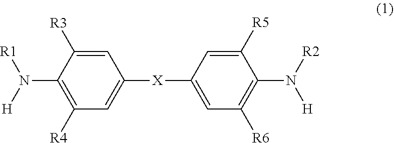

in the formula (1), R1 and R2 each independently represent a hydrogen atom or an alkyl group having 1 to 5 carbon atoms, R3 to R6 each independently represent a hydrogen atom or an alkyl group having 1 to 3 carbon atoms, and X represents —CH₂—, an oxygen atom, —SO₂—, or —C(CF₃)₂—;

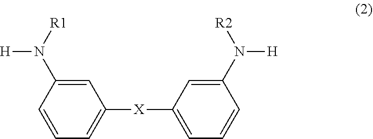

in the formula (2), R1 and R2 each independently represent a hydrogen atom or an alkyl group having 1 to 5 carbon atoms, and X represents —C(CH₃)₂— or an oxygen atom;

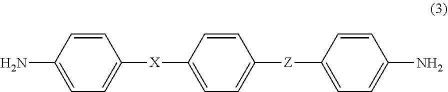

in the formula (3), X represents —C(CH₃)₂— or an oxygen atom, and Z represents —C(CH₃)₂— or an oxygen atom;

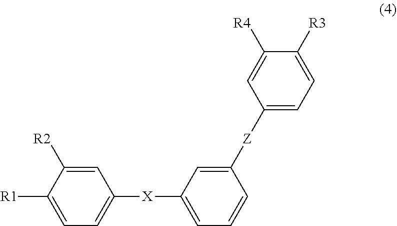

in the formula (4), one of R1 and R2 represents —NH₂ and the other of R1 and R2 represents a hydrogen atom, one of R3 and R4 represents —NH₂ and the other of R3 and R4 represents a hydrogen atom, X represents —C(CH₃)₂— or an oxygen atom, and Z represents —C(CH₃)₂— or an oxygen atom; and

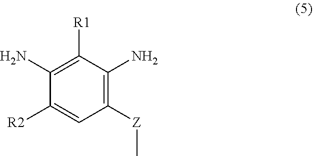

in the formula (5), R1 represents a methyl group or an ethyl group, R2 represents a methyl group, an ethyl group, or —SCH₃, and Z represents —CH₂— or a sulfur atom.

The amine compound (B) enables the cured product to have a high glass transition temperature. Therefore, the cured product and the mounted structure can be improved in heat cycle resistance. It is presumed that the reason is as follows.

The molecule of the amine compound (B) has an aromatic ring, which has high rigidity and exhibits high physical heat resistance. Further, since the amine compound (B) has 4 to 2 active hydrogen groups which are reaction points with the epoxy compound (A) in the molecule, the amine compound (B) can form a high-density crosslinked structure by reacting with the epoxy compound (A). Thereby, the cured product is improved in physical heat resistance. For the above reasons, the glass transition temperature of the cured product is increased. Among the compounds that can be included in the amine compound (B), the compounds having two or more aromatic rings in the molecule (see the compounds represented by the formula (1) to formula (4)) have the aromatic rings substituted with amino groups at the m-position or the p-position with respect to the —X— bond. Therefore, bridge formation between the amine compound (B) and the epoxy compound (A) is hardly inhibited. Further, among the compounds that can be included in the amine compound (B), the compound having only one aromatic ring in the molecule (see the compound represented by the formula (5)) has the aromatic ring substituted with two amino groups in a positional relationship of m-position with each other. Therefore, bridge formation between the amine compound (B) and the epoxy compound (A) is hardly inhibited.

A proportion of the amine compound (B) is preferably 5 mass % or more and 38 mass % or less in the solid content of the composition (X). When the proportion is 5 mass % or more, the glass transition temperature of the cured product can be further increased. When the proportion is 38 mass % or less, an increase in viscosity of the composition (X) is suppressed during storage, and the storage stability of the composition (X) can be enhanced. The proportion is more preferably 7 mass % or more. The proportion is more preferably 37 mass % or less.

The composition (X) may include an activator (C). The activator (C) is a substance that exhibits a flux action in soldering. The flux action means a reducing action to remove an oxide film generated on a solder and a conductor, and an action to decrease the surface tension of a molten solder to increase the wettability of the solder to a metal surface. When the composition (X) contains the activator (C), the conduction reliability between the solder and the conductor can be improved.

The activator (C) preferably contains at least one of an organic acid (C1) having a carboxyl group equivalent of 40 g/eq or more and 400 g/eq or less and a melting point of 220° C. or less and an amine (C2) having a nitrogen atom equivalent of 10 g/eq or more and 300 g/eq or less and a melting point of 220° C. or less. When the melting point of the activator (C) is 220° C. or lower, the oxide film of the solder can be removed before the solder is melted even when a solder having a melting point of around 200° C. or 200° C. or higher is used. The “carboxyl group equivalent” is a value obtained by dividing the mass (g) of one mole of a substance by the number of carboxyl groups per molecule of the substance, and the “nitrogen atom equivalent” is a value obtained by dividing the mass (g) of one mole of a substance by the number of nitrogen atoms per molecule of the substance.

The organic acid (C1) can contain, for example, at least one selected from the group consisting of a rosin component material, adipic acid, glutaric acid, succinic acid, malonic acid, citric acid, core acid, sebacic acid, and pimelic acid. The organic acid (C1) preferably contains at least one selected from the group consisting of succinic acid (carboxyl group equivalent: 59 g/eq), glutaric acid (carboxyl group equivalent: 66 g/eq), adipic acid (carboxyl group equivalent: 73 g/eq), core acid (carboxyl group equivalent: 87 g/eq), sebacic acid (carboxyl group equivalent: 101 g/eq), and Tsunodyme 395 (carboxyl group equivalent: 288 g/eq).

The amine (C2) is not particularly limited as long as it is an amine used as a flux, and can contain, for example, at least one or more selected from the group consisting of various amine salts, alkanolamines, and guanidine. The amine (C2) particularly preferably contains at least one selected from the group consisting of diethanolamine (nitrogen atom equivalent: 105 g/eq), triethanolamine (TEA) (nitrogen atom equivalent: 149 g/eq), triisopropanolamine (nitrogen atom equivalent: 191 g/eq), 1,3-diphenylguanidine (nitrogen atom equivalent: 70 g/eq), and 1,3-di-o-tolylguanidine (nitrogen atom equivalent: 80 g/eq).

The activator (C) may contain components other than the organic acid (C1) and the amine (C2). For example, the activator (C) may contain an organic acid or amine having a melting point of higher than 220° C.

A proportion of the activator (C) is preferably 1.5 mass % or more and 25 mass % or less in the solid content of the composition (X). When the proportion is 4 mass % or more, the flux action is favorably exhibited, and the conduction reliability can be further enhanced between the conductor and the solder. When the proportion is 25 mass % or less, a decrease in the storage stability of the composition (X) is suppressed, a decrease in the glass transition temperature of the cured product is suppressed, and a decrease in joint strength between the conductor and the solder can be suppressed. The proportion is more preferably 2.5 mass % or more. The proportion is more preferably 23 mass % or less.

The composition (X) may contain a thixotropic agent (D). The thixotropic agent (D) is a compound that imparts thixotropy to the composition (X). Thixotropy is a property to decrease the viscosity of a substance when a shear stress is applied. Thixotropy is quantified by thixotropy ratio (thixotropy index). In other words, the thixotropic agent (D) is a compound capable of increasing the thixotropy ratio. For example, under a constant temperature, viscosity is measured under each of two conditions different from each other in the rotational speed of a rotary viscometer, and the ratio of the two viscosities obtained as a result can be defined as the thixotropy ratio.

The thixotropic agent (D) contains, for example, at least one selected from the group consisting of 1,3:2,4-bis-O-benzylidene-D-glucitol (dibenzylidene sorbitol) (for example, manufactured by New Japan Chemical Co., Ltd., product name: GEL ALL D), 1,3:2,4-bis-0-(4-methylbenzylidene)-D-sorbitol (for example, manufactured by New Japan Chemical Co., Ltd., product name: GEL ALL MD), and N,N′-methylenebis (stearoamide) (for example, manufactured by Mitsubishi Chemical Corporation, product name: BISAMIDE LA).

A proportion of the thixotropic agent (D) is preferably 1 mass % or more and 7 mass % or less in the solid content of the composition (X). In this case, the composition (X) can have an appropriate thixotropy ratio.

The composition (X) may contain a solvent (E) as necessary. The solvent (E) is preferably an ether-based solvent. The solvent (E) preferably contains glycol ethers. For example, the solvent (E) contains at least one selected from the group consisting of diethylene glycol diethyl ether, ethylene glycol mono-2-ethyl hexyl ether, hexyl diglycol, and the like.

The amount of the solvent (E) may be appropriately set so that the composition (X) has an appropriate viscosity. A proportion of the solvent is, for example, 2 mass % or more and 25 mass % or less in the composition (X).

The composition (X) may contain an additive (F), which is a component other than the epoxy compound (A), the amine compound (B), the activator (C), the thixotropic agent (D), and the solvent (E). The additive (F) contains, for example, at least one selected from the group consisting of a phenol compound, an imidazole compound, a benzoxazine compound, a component modifier, a filler, and the like. A proportion of the additive (F) is preferably 5 mass % or less in the solid content of the composition (X).

The viscosity of the composition (X) is preferably 10 Pa·s or more and 250 Pa-s or less. In this case, the composition (X) is easily applied to the joint between the conductor and the solder bump. That is, the coating property of the composition (X) can be improved. The viscosity is more preferably 25 Pa·s or more, and still more preferably 30 Pa·s or more. The viscosity is more preferably 120 Pa·s or less, and still more preferably 110 Pa·s or less. The viscosity of the composition (X) is a value measured under conditions of 25° C. and a rotation speed of 2.5 rpm using an E-type viscometer.

The thixotropy ratio of the composition (X) is preferably 1.5 or more and 8 or less. In this case, the coating property of the composition (X) can be enhanced. The thixotropy ratio is the ratio value η_{0.25}/η_{2.5} between the viscosity η_{0.25} measured by an E-type viscometer under the conditions of 25° C. and a rotation speed of 0.25 rpm and the viscosity η_{2.5} measured by an E-type viscometer under the conditions of 25° C. and a rotation speed of 2.5 rpm. The thixotropy ratio is more preferably 1.5 or more, and still more preferably 2.0 or more. The thixotropy ratio is more preferably 5.0 or less, and still more preferably 4.5 or less.

The glass transition temperature of the cured product of the composition (X) is preferably 100° C. or higher. In this case, the heat resistance of the cured product is more easily improved, and thus the heat cycle resistance of the cured product and the mounted structure can be further improved. The glass transition temperature is more preferably 125° C. or higher.

### 2. Mounted Structure

Reinforcing part 4 in mounted structure 1 can be produced from the composition (X).

Mounted structure 1 of the exemplary embodiment includes base material 2, mounted component 3, solder bump 32, and reinforcing part 4. Base material 2 includes first conductor 21. Mounted component 3 includes second conductor 31. Solder bump 32 is interposed between first conductor 21 and second conductor 31. Solder bump 32 electrically connects first conductor 21 to second conductor 31. Reinforcing part 4 includes a cured product of the composition (X), and covers at least one of joint 20 between first conductor 21 and solder bump 32 or joint 20 between second conductor 31 and solder bump 32.

FIG. 1 illustrates mounted structure 1 according to the exemplary embodiment.

Base material 2 is, for example, a mother substrate, a package substrate, or an interposer substrate. Base material 2 includes an insulating substrate such as a glass epoxy substrate, a polyimide substrate, a polyester substrate, or a ceramic substrate, and first conductor 21 prepared on the insulating substrate. First conductor 21 is, for example, a conductor wiring made of metal.

Mounted component 3 is, for example, a semiconductor chip. More specifically, mounted component 3 is a flip-chip type chip such as a ball grid array (BGA), a land grid array (LGA), or a chip size package (CSP). Mounted component 3 may be a wafer level package (WLP). Mounted component 3 may be a package-on-package (PoP) type chip.

Mounted component 3 includes second conductor 31. Second conductor 31 is, for example, a pad (terminal electrode) on a semiconductor chip. For example, when mounted component 3 is a BGA, mounted component 3 is a package formed by sealing a die mounted on a substrate with a sealing resin, and second conductor 31 is a terminal electrode electrically connected to the die. For example, when mounted component 3 is a WLP, mounted component 3 includes a silicon substrate provided with a rewiring layer, and second conductor 31 is a pillar electrically connected to the rewiring layer. Note that the structure of mounted component 3 is not limited to the above, and is an appropriate structure according to the type of mounted component 3.

Solder bump 32 is disposed between first conductor 21 of base material 2 and second conductor 31 of mounted component 3. Solder bump 32 electrically connects first conductor 21 to second conductor 31. Solder bump 32 may be, for example, Sn—Ag—Cu (SAC) solder or Sn—Bi (tin copper) solder.

When solder bump 32 is the SAC solder, the melting point of solder bump 32 is, for example, 217° C. or more and 230° C. or less.

The Sn—Bi solder may contain at least one material selected from the group consisting of Ag, Ni, Fe, Ge, Cu, In, and the like in addition to Sn and Bi. In order to improve the mechanical performance of the Sn—Bi solder, the Sn—Bi solder preferably contains at least one material selected from the group consisting of Ag, Ni, Fe, Ge, and the like.

As described above, reinforcing part 4 includes the cured product of the composition (X). In mounted structure 1 illustrated in FIG. 1, reinforcing part 4 covers joint 20 between solder bump 32 and first conductor 21. Therefore, reinforcing part 4 can reinforce joint 20 between solder bump 32 and first conductor 21. Therefore, conduction failure between first conductor 21 and solder bump 32 is suppressed, and mounted structure 1 can have good connection reliability. In the exemplary embodiment, reinforcing part 4 can have high heat resistance and high heat cycle resistance. As a result, mounted structure 1 can have high heat resistance and high heat cycle resistance.

In the exemplary embodiment, joint 20 between second conductor 31 and solder bump 32 is covered with reinforcing part 4.

The method for producing mounted structure 1 will be described.

The composition (X) is disposed at least one of between first conductor 21 and solder bump 32 or between second conductor 31 and solder bump 32. In this state, mounted component 3 is flip-mounted on base material 2 by soldering. Thus, mounted structure 1 including reinforcing part 4 can be produced.

Specifically, at first, the composition (X), base material 2 including first conductor 21, mounted component 3 including second conductor 31, and solder bump 32 are prepared.

The composition (X) is disposed on first conductor 21 by, for example, applying the composition (X) onto first conductor 21 of base material 2. The method for applying the composition (X) is a printing method, a transfer method, or the like, but is not limited thereto. Examples of the printing method include an inkjet method.

Solder bump 32 is provided on mounted component 3 so that solder bump 32 is in contact with second conductor 31. Solder bump 32 is, for example, a solder ball.

Base material 2 and mounted component 3 are disposed so that solder bump 32 is in contact with the composition (X) while first conductor 21 of base material 2 and second conductor 31 of mounted component 3 face each other. Thus, the composition (X) is disposed between solder bump 32 and first conductor 21.

In this state, solder bump 32 and the composition (X) are heated in a heating furnace such as a reflow furnace.

When solder bump 32 and the composition (X) are heated, for example, first, solder bump 32 and the composition (X) are heated to around the melting point of the composition (X). For example, the composition (X) and solder bump 32 are heated to a temperature of 140° C. or more and 160° C. or less. As a result, the viscosity of the composition (X) decreases to cause the composition (X) flow, and thus solder bump 32 comes into contact with first conductor 21.

Subsequently, solder bump 32 and the composition (X) are heated to a temperature higher than the melting point of the solder. For example, the composition (X) and solder bump 32 are heated to a temperature of 232° C. or more and 255° C. or less. As a result, solder bump 32 melts to wet and spread between first conductor 21 and second conductor 31. Then, first conductor 21 and second conductor 31 are electrically connected via solder bump 32.

Subsequently, as the composition (X) is further heated, curing of the composition (X) proceeds, and reinforcing part 4 including the cured product of the composition (X) is produced.

Thus, mounted structure 1 including reinforcing part 4 is produced.

### 3. Modifications

The first modification and the second modification of mounted structure 1 will be described with reference to FIG. 2 and FIG. 3, respectively. Note that, in these modifications, the components similar to those of mounted structure 1 of the exemplary embodiment are denoted by the same reference numerals as those of the exemplary embodiment in the drawings, and the detailed description thereof will be appropriately omitted.

In mounted structure 1 of the first modification shown in FIG. 2, joint 20 between first conductor 21 of mounted component 3 and solder bump 32 is not covered with reinforcing part 4, and joint 20 between second conductor 31 of mounted component 3 and solder bump 32 is covered with reinforcing part 4. Even in this case, the heat cycle resistance of mounted structure 1 can be improved.

When mounted structure 1 of the first modification is produced, for example, in a state where solder bump 32 is provided on base material 2 so that solder bump 32 is in contact with first conductor 21, base material 2 and mounted component 3 are disposed so that solder bump 32 is in contact with the composition (X) while first conductor 21 of base material 2 and second conductor 31 of mounted component 3 face each other. Thus, the composition (X) is interposed between solder bump 32 and second conductor 31.

In this state, solder bump 32 and the composition (X) are heated in a heating furnace such as a reflow furnace. As a result, first conductor 21 and second conductor 31 are electrically connected via solder bump 32, and joint 20 between second conductor 31 of mounted component 3 and solder bump 32 is covered with reinforcing part 4 including the cured product of the composition (X). Thus, mounted structure 1 is produced.

In mounted structure 1 of the second modification shown in FIG. 3, joint 20 between first conductor 21 of mounted component 3 and solder bump 32 and joint 20 between second conductor 31 of mounted component 3 and solder bump 32 are each covered with reinforcing part 4. That is, mounted structure 1 includes reinforcing part 4 that covers joint 20 between first conductor 21 of mounted component 3 and solder bump 32, and reinforcing part 4 that covers joint 20 between second conductor 31 of mounted component 3 and solder bump 32. Even in this case, the heat cycle resistance of mounted structure 1 can be improved.

When mounted structure 1 of the second modification is produced, for example, the composition (X) is disposed on each of first conductor 21 and second conductor 31. In this state, base material 2 and mounted component 3 are disposed so that first conductor 21 of base material 2 and second conductor 31 of mounted component 3 face each other, and solder bump 32 is interposed between first conductor 21 and second conductor 31 so that solder bump 32 is in contact with both the composition (X) on first conductor 21 and the composition (X) on second conductor 31.

In this state, solder bump 32 and the composition (X) are heated in a heating furnace such as a reflow furnace. As a result, first conductor 21 and second conductor 31 are electrically connected via solder bump 32. In addition, each of joint 20 between first conductor 21 of base material 2 and solder bump 32 and joint 20 between second conductor 31 of mounted component 3 and solder bump 32 is covered with reinforcing part 4 including the cured product of the composition (X). Thus, mounted structure 1 is produced.

Optionally, first, first conductor 21 and solder bump 32 are joined, and joint 20 between first conductor 21 and solder bump 32 are covered with reinforcing part 4, and then, second conductor 31 and solder bump 32 are joined, and joint 20 between second conductor 31 and solder bump 32 are covered with reinforcing part 4. Optionally, first, second conductor 31 and solder bump 32 are joined, and joint 20 between second conductor 31 and solder bump 32 are covered with reinforcing part 4, and then, first conductor 21 and solder bump 32 are joined, and joint 20 between first conductor 21 and solder bump 32 are covered with reinforcing part 4.

In addition, reinforcing part 4 covering joint 20 between second conductor 31 and solder bump 32 and reinforcing part 4 covering joint 20 between first conductor 21 and solder bump 32 may be separated or may be integrated without being separated.

### 4. Embodiments

The reinforcing resin composition according to the first embodiment includes: an epoxy compound (A); and an amine compound (B) including at least one selected from the group consisting of a compound (B1) represented by a following formula (1), a compound (B2) represented by a following formula (2), a compound (B3) represented by a following formula (3), a compound (B4) represented by a following formula (4), and a compound (B5) represented by a following formula (5):

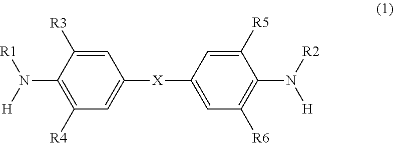

in the formula (1), R1 and R2 each independently represent a hydrogen atom or an alkyl group having 1 to 5 carbon atoms, R3 to R6 each independently represent a hydrogen atom or an alkyl group having 1 to 3 carbon atoms, and X represents —CH₂—, an oxygen atom, —SO₂—, or —C(CF₃)₂—;

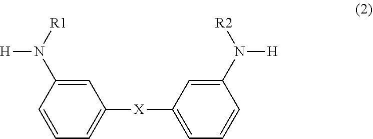

in the formula (2), R1 and R2 each independently represent a hydrogen atom or an alkyl group having 1 to 5 carbon atoms, and X represents —C(CH₃)₂— or an oxygen atom;

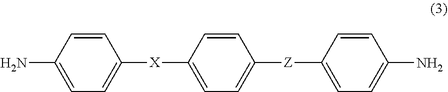

in the formula (3), X represents —C(CH₃)₂— or an oxygen atom, and Z represents —C(CH₃)₂— or an oxygen atom;

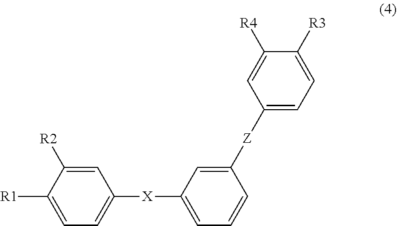

in the formula (4), one of R1 and R2 represents —NH₂ and the other of R1 and R2 represents a hydrogen atom, one of R3 and R4 represents —NH₂ and the other of R3 and R4 represents a hydrogen atom, X represents —C(CH₃)₂— or an oxygen atom, and Z represents —C(CH₃)₂— or an oxygen atom; and

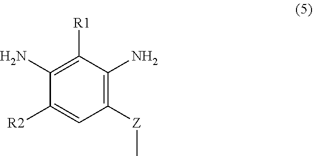

in the formula (5), R1 represents a methyl group or an ethyl group, R2 represents a methyl group, an ethyl group, or —SCH₃, and Z represents —CH₂— or a sulfur atom.

According to the embodiment, the glass transition temperature of the cured product of the reinforcing resin composition can be increased to improve the heat cycle resistance of the cured product.

According to the second embodiment, in the first embodiment, a proportion of the epoxy compound (A) is 48 mass % or more and 85 mass % or less in a solid content of the reinforcing resin composition, and a proportion of the amine compound (B) is 5 mass % or more and 38 mass % or less in a solid content of the reinforcing resin composition.

According to the third embodiment, in the first or second embodiment, the epoxy compound (A) includes an epoxy compound (A1) including at least one selected from the group consisting of a naphthalene epoxy resin, a biphenyl aralkyl epoxy resin, a trisphenol methane epoxy resin, a biphenyl epoxy resin, and a dicyclopentadiene epoxy resin.

According to the fourth embodiment, in the third embodiment, a proportion of the epoxy compound (A1) is 16 mass % or more and 35 mass % or less in a solid content of the reinforcing resin composition.

According to the fifth embodiment, in any one of the first to fourth embodiments, the reinforcing resin composition further includes an activator (C).

According to the sixth embodiment, in the fifth embodiment, a proportion of the activator (C) is 1.5 mass % or more and 25 mass % or less in a solid content of the reinforcing resin composition.

According to the seventh embodiment, in any one of the first to sixth embodiments, the reinforcing resin composition further includes a thixotropic agent (D).

According to the eighth embodiment, in the seventh embodiment, a proportion of the thixotropic agent (D) is 1 mass % or more and 7 mass % or less in a solid content of the reinforcing resin composition.

According to the ninth embodiment, in any one of the first to eighth embodiments, a cured product of the reinforcing resin composition has a glass transition temperature of 100° C. or higher.

Mounted structure (1) according to the tenth embodiment includes: base material (2) including first conductor (21); mounted component (3) having second conductor (31); solder bump (32) disposed between first conductor (21) and second conductor (31), solder bump (32) electrically connecting first conductor (21) to second conductor (31); and reinforcing part (4) including a cured product of the reinforcing resin composition according to any one of the first to ninth embodiments. Reinforcing part (4) covers at least one of joint (20) between first conductor (21) and solder bump (32) or joint (20) between second conductor (31) and solder bump (32).

According to the embodiment, by increasing the glass transition temperature of reinforcing part (4) to enhance the heat cycle resistance, the heat cycle resistance of mounted structure (1) can be enhanced.

### EXAMPLES

Hereinafter, specific examples of the present disclosure will be presented. Note that the present disclosure is not limited only to the following examples.

### 1. Preparation of Resin Composition

The components shown in Table 1 are mixed in the proportion shown in Table 1 to obtain resin compositions. The details of the components shown in Table 1 are as follows.
Epoxy compound #1: A mixture of a naphthalene epoxy resin represented by the formula (15) and a naphthalene epoxy resin represented by the formula (16). Epoxy group equivalent 215. Manufactured by DIC Corporation. Product name HP-6000L.
Epoxy compound #2: A naphthalene epoxy resin represented by the formula (11). Epoxy group equivalent 136 to 148. Manufactured by DIC Corporation. Product name HP-4032D.
Epoxy compound #3: A trisphenol methane epoxy resin represented by the formula (18). Epoxy group equivalent 162. Manufactured by DIC Corporation. Product name HP-7250.
Epoxy compound #4: A biphenyl aralkyl epoxy resin represented by the formula (20). Epoxy group equivalent 280 to 300. Manufactured by Nippon Kayaku Co., Ltd. Product name NC-3000-H.
Epoxy compound #5: A biphenyl epoxy resin represented by the formula (21). Epoxy group equivalent 187 to 197. Manufactured by Mitsubishi Chemical Corporation. Product name YX4000H.
Epoxy compound #6: A dicyclopentadiene epoxy resin represented by the formula (22). Epoxy group equivalent 280 to 292. Manufactured by DIC Corporation. Product name HP-7200HHH.
Epoxy compound #7: A bisphenol epoxy resin that is liquid at 25° C. Manufactured by NIPPON STEEL Chemical & Material Co., Ltd. Product name YD8125.
Epoxy compound #8: A bisphenol epoxy resin that is liquid at 25° C. Manufactured by NIPPON STEEL Chemical & Material Co., Ltd. Product name YDF8170.
Amine compound #1: 4,4′-diaminodiphenylsulfone represented by the following formula. Manufactured by Tokyo Chemical Industry Co., Ltd.

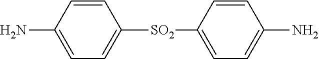

Amine compound #2: 3,3′-diaminodiphenylsulfone represented by the following formula. Manufactured by Tokyo Chemical Industry Co., Ltd.

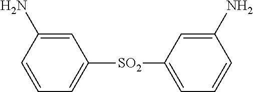

Amine compound #3: 4,4′-methylenebis (2-ethylaniline) represented by the following formula. Manufactured by Tokyo Chemical Industry Co., Ltd.

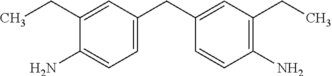 [SMILES: CCc1cc(Cc2ccc(N)c(CC)c2)ccc1N]

Amine compound #4: 4,4′-methylenebis (2-ethyl-6-methylaniline) represented by the following formula. Manufactured by Tokyo Chemical Industry Co., Ltd.

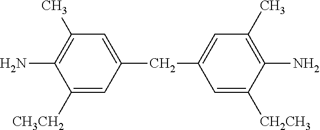

Amine compound #5: 4,4′-methylenebis [N-(1-methylpropyl) aniline] represented by the following formula. Manufactured by Mitsui Fine Chemicals, Inc.

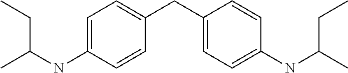 [SMILES: CCC(C)Nc1ccc(Cc2ccc(NC(C)CC)cc2)cc1]

Amine compound #6: 4,4′-diaminodiphenyl ether represented by the following formula. Manufactured by Tokyo Chemical Industry Co., Ltd.

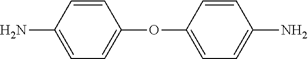 [SMILES: Nc1ccc(Oc2ccc(N)cc2)cc1]

Amine compound #7: 1,3-bis(3-aminophenoxy) benzene represented by the following formula. Manufactured by Tokyo Chemical Industry Co., Ltd.

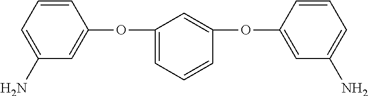 [SMILES: Nc1cccc(Oc2cccc(Oc3cccc(N)c3)c2)c1]

Amine compound #8: Diethyltoluenediamine represented by the following formula. Manufactured by Mitsui Fine Chemicals, Inc.

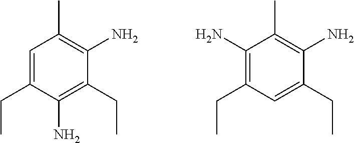

Amine compound #9: Dimethylthiotoluenediamine represented by the following formula. Manufactured by Mitsui Fine Chemicals, Inc.

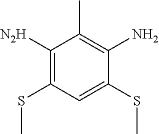

Phenol compound: Diallyl bisphenol A represented by the following formula.

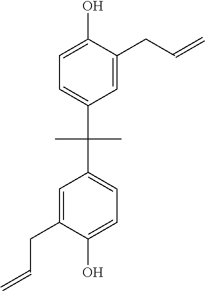 [SMILES: C=CCc1cc(C(C)(C)c2ccc(O)c(CC=C)c2)ccc1O]

Activator #1: Adipic acid. Manufactured by Tokyo Chemical Industry Co., Ltd.
Activator #2: Glutaric acid. Manufactured by Tokyo Chemical Industry Co., Ltd.
Activator #3: Triethanolamine. Manufactured by Tokyo Chemical Industry Co., Ltd.
Activator #4: 1,3-diphenylguanidine. Manufactured by Tokyo Chemical Industry Co., Ltd.
Activator #5: Manufactured by TSUNO FOOD INDUSTRIAL CO., LTD. Product name: Tsunodyme 395. Containing 94% dimer acid.
Thixotropic agent #1:1,3:2,4-bis-O-benzylidene-D-glucitol (dibenzylidene sorbitol). Manufactured by New Japan Chemical Co., Ltd. Product name: GEL ALL D.
Thixotropic agent #2: 1,3:2,4-bis-O-(4-methylbenzylidene)-D-sorbitol. Manufactured by New Japan Chemical Co., Ltd. Product name: GEL ALL MD.
Thixotropic agent #3: N,N′-methylenebis (stearoamide). Manufactured by Mitsubishi Chemical Corporation. Product name BISAMIDE LA.
Solvent #1: Diethylene glycol diethyl ether. Manufactured by NIPPON NYUKAZAI CO., LTD.
Solvent #2: Diethylene glycol monohexyl ether. Manufactured by NIPPON NYUKAZAI CO., LTD.

### 2. Evaluation

The resin composition was subjected to the following evaluation tests. The results are shown in Table 1.

### (1) Viscosity

Using an E-type viscometer (manufactured by Toki Sangyo Co., Ltd., product number: RE-215U), the viscosity of the resin composition was measured at 25° C. and a rotation speed of 2.5 rpm.

### (2) Thixotropy Ratio

Using an E-type viscometer (manufactured by Toki Sangyo Co., Ltd., product number: RE-215U), the viscosity η_{0.25} of the resin composition at 25° C. and a rotation speed of 0.25 rpm and the viscosity η_{2.5} thereof at 25° C. and a rotation speed of 2.5 rpm were measured. Based on the measurement results, the ratio value η_{0.25}/η_{2.5} was calculated as the thixotropy ratio.

### (3) Coating Property

As for a substrate having a plurality of Ni—Pd—Au alloy pads arranged at intervals of 0.5 mm and having a diameter of 300 m, on each pad, the resin composition was applied using a printing machine (SP-80V, manufactured by Panasonic Smart Factory Solutions Co., Ltd.) to form a coating film of the resin composition covering each pad. The state of the coating film was observed with a microscope and evaluated according to the following criteria.

A: There is no problem in the shape of the coating film.

B: There are bridges between coating films and coating film defects, but there is no problem in practical use.

C: There are many bridges between coating films and coating film defects.

### (4) Wet Spreadability

In accordance with JIS Z 3198-3, the resin composition was disposed on a copper plate, a solder sample was placed thereon, and in this state, the resin composition and the solder sample were heated. Based on the results, the spreading rate of the solder sample was calculated. As the solder sample, a solder ball having a diameter of 300 m and made of SAC305 (composition: Sn: 96.5%, Ag: 3.0%, and Cu: 0.5%, melting point 219° C.), which is a lead-free solder, was used. As the heating conditions, first, the temperatures of the resin composition and the solder sample were raised to a range of 220 to 225° C., and the temperature was maintained in this range for 60 seconds. Subsequently, the temperature was lowered to room temperature.

When the spreading rate is 50% or more, it can be evaluated that the wet spreadability is excellent, and when the spreading rate is 60% or more, it can be evaluated that the wet spreadability is particularly excellent.

### (5) Storage Stability

The initial viscosity of the resin composition was measured by the method of “(1) Viscosity” described above. Subsequently, the resin composition was stored at a temperature of 25° C. The storage stability was evaluated from the time until the viscosity of the resin composition measured by the method of “(1) Viscosity” described above reached 120% of the initial viscosity from the start of storage.

When the time is 20 hours or more, it can be evaluated that the storage stability is excellent, and when the time is 24 hours or more, it can be evaluated that the storage stability is particularly excellent.

### (6) Glass Transition Temperature (Tg)

The resin composition was heated at 150° C. for 1 hour and then heated at 200° C. for 300 hours to be cured, thereby preparing a sample piece. The glass transition temperature of this sample was measured by thermomechanical analysis (in accordance with TMA, JIS K 7197:1991).

When the glass transition temperature is 100° C. or higher, it can be evaluated that the cured product of the resin composition is excellent in heat resistance and heat cycle resistance, and when the glass transition temperature is 125° C. or higher, it can be evaluated that the cured product is particularly excellent in heat resistance and heat cycle resistance.

### (7) Solder Joint Strength

Prepared were: a substrate having a plurality of Ni—Pd—Au alloy pads arranged at intervals of 0.5 mm and having a diameter of 300 am; a metal mask having a thickness of 60 μm and having 300 m diameter openings corresponding to the pads; and a solder ball having a diameter of 300 μm and made of SAC305 (composition: Sn: 96.5%, Ag: 3.0%, and Cu: 0.5%, melting point 219° C.), which is a lead-free solder.

Using the metal mask, the resin composition was applied onto the pad to prepare a coating film. The solder ball was disposed on the coating film. In this state, the resin composition and the solder ball were heated in a reflow furnace having a peak temperature of 260° C. to join the solder ball to the pad.

The joint strength of the solder ball to the pad was measured by performing a bump shear test in accordance with JETA ED-4703 using a bond tester (manufactured by Nordson Advanced Technology).

When the joint strength is 1.96 N or more (200 g for more), it can be evaluated that the joint strength is excellent, and when the joint strength is 2.16 N or more (220 g for more), it can be evaluated that the joint strength is particularly excellent.

TABLE 1

| | | Examples | | | | | |
|---|---|---|---|---|---|---|---|
| | | 1 | 2 | 3 | 4 | 5 | 6 |
| Composition/ | Epoxy | 22.2 | | | | | |
| part by mass | compound #1 | | | | | | |
| | Epoxy | | 25 | | | | |
| | compound #2 | | | | | | |
| | Epoxy | | | 17.2 | | | |
| | compound #3 | | | | | | |
| | Epoxy | | | | 22.2 | | |
| | compound #4 | | | | | | |
| | Epoxy | | | | | 22.2 | |
| | compound #5 | | | | | | |
| | Epoxy | | | | | | 22.2 |
| | compound #6 | | | | | | |
| | Epoxy | 28.5 | 29.5 | 21.3 | 28.5 | 28.5 | 28.5 |
| | compound #7 | | | | | | |
| | Epoxy | 12.6 | 18.8 | 7.6 | 12.6 | 12.6 | 12.6 |
| | compound #8 | | | | | | |
| | Amine | 11.7 | 9.2 | | | | |
| | compound #1 | | | | | | |
| | Amine | | | 23.9 | | | |
| | compound #2 | | | | | | |
| | Amine | | | | 11.7 | | |
| | compound #3 | | | | | | |
| | Amine | | | | | 11.7 | |
| | compound #4 | | | | | | |
| | Amine | | | | | | 5 |
| | compound #5 | | | | | | |
| | Amine | | | | | | 6.7 |
| | compound #6 | | | | | | |
| | Amine | | | | | | |
| | compound #7 | | | | | | |
| | Amine | | | | | | |
| | compound #8 | | | | | | |
| | Amine | | | | | | |
| | compound #9 | | | | | | |
| | Phenol | | | | | | |
| | compound | | | | | | |
| | Activator #1 | | | | | | |
| | Activator #2 | 0.8 | 0.8 | 0.8 | 0.8 | 0.8 | 0.8 |
| | Activator #3 | | | | | | |
| | Activator #4 | | | | | | |
| | Activator #5 | 6.8 | 6.8 | 6.8 | 6.8 | 6.8 | 6.8 |
| | Thixotropic | 2.4 | 2.4 | 4.4 | 2.4 | 2.4 | 2.4 |
| | agent #1 | | | | | | |
| | Thixotropic | | | | | | |
| | agent #2 | | | | | | |
| | Thixotropic | | | | | | |
| | agent #3 | | | | | | |
| | Solvent #1 | 15 | 7.5 | 18 | 15 | 15 | 15 |
| | Solvent #2 | | | | | | |
| Proportion in | Epoxy | 74.5 | 79.2 | 56.2 | 74.5 | 74.5 | 74.5 |
| solid content/ | compound (A) | | | | | | |
| mass % | Epoxy | 26.1 | 27.0 | 21.0 | 26.1 | 26.1 | 26.1 |
| | compound (A1) | | | | | | |
| | Amine | 13.8 | 9.9 | 29.1 | 13.8 | 13.8 | 13.8 |
| | compound (B) | | | | | | |
| | Activator (C) | 8.9 | 8.2 | 9.3 | 8.9 | 8.9 | 8.9 |
| | Thixotropic | 2.8 | 2.6 | 5.4 | 2.8 | 2.8 | 2.8 |
| | agent (D) | | | | | | |
| Evaluation | Viscosity | 52 | 88 | 40 | 60 | 68 | 58 |
| | (Pa · s) | | | | | | |
| | Thixotropy | 2.8 | 3.2 | 3.6 | 3.0 | 3.1 | 2.8 |
| | ratio | | | | | | |
| | Coating | A | B | A | A | A | A |
| | property | | | | | | |
| | Wet | 68% | 65% | 70% | 66% | 69% | 72% |
| | spreadability | | | | | | |
| | Storage | 30 | 32 | 22 | 28 | 26 | 27 |
| | stability | | | | | | |
| | (time) | | | | | | |
| | Tg (° C.) | 130 | 128 | 110 | 132 | 129 | 131 |
| | Solder joint | 2.30 | 2.28 | 2.24 | 2.22 | 2.29 | 2.25 |
| | strength (N) | | | | | | |

TABLE 2

| | | Examples | | | | | |
|---|---|---|---|---|---|---|---|
| | | 7 | 8 | 9 | 10 | 11 | 12 |
| Composition/ | Epoxy | 22.2 | 11.1 | | 21.3 | 22.2 | 22.2 |
| part by mass | compound #1 | | | | | | |
| | Epoxy | | 11.1 | | | | |
| | compound #2 | | | | | | |
| | Epoxy | | | | | | |
| | compound #3 | | | | | | |
| | Epoxy | | | 15 | | | |
| | compound #4 | | | | | | |
| | Epoxy | | | 7.2 | | | |
| | compound #5 | | | | | | |
| | Epoxy | | | | | | |
| | compound #6 | | | | | | |
| | Epoxy | 28.5 | 28.5 | 28.5 | 24.5 | 28.5 | 28.5 |
| | compound #7 | | | | | | |
| | Epoxy | 12.6 | 12.6 | 12.6 | 15.9 | 12.6 | 12.6 |
| | compound #8 | | | | | | |
| | Amine | | 11.7 | | 11.7 | 11.7 | 11.7 |
| | compound #1 | | | | | | |
| | Amine | | | 11.7 | | | |
| | compound #2 | | | | | | |
| | Amine | | | | | | |
| | compound #3 | | | | | | |
| | Amine | | | | | | |
| | compound #4 | | | | | | |
| | Amine | | | | | | |
| | compound #5 | | | | | | |
| | Amine | | | | | | |
| | compound #6 | | | | | | |
| | Amine | 4 | | | | | |
| | compound #7 | | | | | | |
| | Amine | 4 | | | | | |
| | compound #8 | | | | | | |
| | Amine | 3.7 | | | | | |
| | compound #9 | | | | | | |
| | Phenol | | | | | | |
| | compound | | | | | | |
| | Activator #1 | | | | | | 0.8 |
| | Activator #2 | 0.8 | 0.8 | 0.8 | 1.2 | 0.4 | |
| | Activator #3 | | | | | | 1.2 |
| | Activator #4 | | | | | | 1.2 |
| | Activator #5 | 6.8 | 6.8 | 6.8 | 18 | 4.8 | 4.4 |
| | Thixotropic | 2.4 | 2.4 | 2.4 | 2.4 | 2.4 | 2.4 |
| | agent #1 | | | | | | |
| | Thixotropic | | | | | | |
| | agent #2 | | | | | | |
| | Thixotropic | | | | | | |
| | agent #3 | | | | | | |
| | Solvent #1 | 15 | 15 | 15 | 5 | 17.4 | 15 |
| | Solvent #2 | | | | | | |
| Proportion in | Epoxy | 74.5 | 74.5 | 74.5 | 64.9 | 76.6 | 74.5 |
| solid content/ | compound (A) | | | | | | |
| mass % | Epoxy | 26.1 | 26.1 | 26.1 | 22.4 | 26.9 | 26.1 |
| | compound (A1) | | | | | | |
| | Amine | 13.8 | 13.8 | 13.8 | 12.3 | 14.2 | 13.8 |
| | compound (B) | | | | | | |
| | Activator (C) | 8.9 | 8.9 | 8.9 | 20.2 | 6.3 | 8.9 |
| | Thixotropic | 2.8 | 2.8 | 2.8 | 2.5 | 2.9 | 2.8 |
| | agent (D) | | | | | | |
| Evaluation | Viscosity | 66 | 70 | 53 | 61 | 59 | 62 |
| | (Pa · s) | | | | | | |
| | Thixotropy | 2.9 | 2.5 | 2.9 | 3.3 | 2.8 | 2.7 |
| | ratio | | | | | | |
| | Coating | A | A | A | A | A | A |
| | property | | | | | | |
| | Wet | 67% | 64% | 68% | 71% | 55% | 66% |
| | spreadability | | | | | | |
| | Storage | 29 | 25 | 27 | 21 | 29 | 26 |
| | stability | | | | | | |
| | (time) | | | | | | |
| | Tg (° C.) | 128 | 132 | 126 | 118 | 130 | 128 |
| | Solder joint | 2.21 | 2.27 | 2.26 | 2.08 | 2.06 | 2.18 |
| | strength (N) | | | | | | |

TABLE 3

| | | | | | | Comparative |
|---|---|---|---|---|---|---|
| | | Examples | | | | example |
| | | 13 | 14 | 15 | 16 | 1 |
| Composition/ | Epoxy | 22.2 | | | 22.2 | 22.2 |
| part by mass | compound #1 | | | | | |
| | Epoxy | | 27.5 | | | |
| | compound #2 | | | | | |
| | Epoxy | | | 17.2 | | |
| | compound #3 | | | | | |
| | Epoxy | | | | | |
| | compound #4 | | | | | |
| | Epoxy | | | | | |
| | compound #5 | | | | | |
| | Epoxy | | | | | |
| | compound #6 | | | | | |
| | Epoxy | 28.5 | 30.5 | 22.3 | 28.5 | 28.5 |
| | compound #7 | | | | | |
| | Epoxy | 12.6 | 19.8 | 6.6 | 12.6 | 12.6 |
| | compound #8 | | | | | |
| | Amine | 11.7 | 8.2 | | 13.9 | |
| | compound #1 | | | | | |
| | Amine | | | 31.9 | | |
| | compound #2 | | | | | |
| | Amine | | | | | |
| | compound #3 | | | | | |
| | Amine | | | | | |
| | compound #4 | | | | | |
| | Amine | | | | | |
| | compound #5 | | | | | |
| | Amine | | | | | |
| | compound #6 | | | | | |
| | Amine | | | | | |
| | compound #7 | | | | | |
| | Amine | | | | | |
| | compound #8 | | | | | |
| | Amine | | | | | |
| | compound #9 | | | | | |
| | Phenol | | | | | 11.7 |
| | compound | | | | | |
| | Activator #1 | | | | | |
| | Activator #2 | 0.8 | 0.8 | 1.8 | 0.4 | 0.8 |
| | Activator #3 | | | | | |
| | Activator #4 | | | | | |
| | Activator #5 | 6.8 | 5.8 | 7.8 | 2.6 | 6.8 |
| | Thixotropic | | 2.4 | 2.4 | 2.4 | 2.4 |
| | agent #1 | | | | | |
| | Thixotropic | 1 | | | | |
| | agent #2 | | | | | |
| | Thixotropic | 1.4 | | | | |
| | agent #3 | | | | | |
| | Solvent #1 | 7 | 5 | 10 | 17.4 | 15 |
| | Solvent #2 | 8 | | | | |
| Proportion in | Epoxy | 74.5 | 81.9 | 51.2 | 76.6 | 74.5 |
| solid content/ | compound (A) | | | | | |
| mass % | Epoxy | 26.1 | 28.9 | 19.1 | 26.9 | 26.1 |
| | compound (A1) | | | | | |
| | Amine | 13.8 | 8.6 | 35.4 | 16.8 | 0.0 |
| | compound (B) | | | | | |
| | Activator (C) | 8.9 | 6.9 | 10.7 | 3.6 | 8.9 |
| | Thixotropic | 2.8 | 2.5 | 2.7 | 2.9 | 2.8 |
| | agent (D) | | | | | |
| Evaluation | Viscosity | 65 | 98 | 77 | 56 | 69 |
| | (Pa · s) | | | | | |
| | Thixotropy | 3.1 | 2.3 | 2.8 | 3.1 | 2.9 |
| | ratio | | | | | |
| | Coating | A | C | A | A | A |
| | property | | | | | |
| | Wet | 68% | 47% | 69% | 43% | 65% |
| | spreadability | | | | | |
| | Storage | 28 | 25 | 17 | 27 | 29 |
| | stability | | | | | |
| | (time) | | | | | |
| | Tg (° C.) | 128 | 132 | 120 | 128 | 95 |
| | Solder joint | 2.26 | 2.24 | 2.27 | 1.88 | 1.86 |
| | strength (N) | | | | | |

What is claimed is:

1. A reinforcing resin composition comprising:
an epoxy compound (A); and
an amine compound (B) including at least one selected from the group consisting of a compound (B1) represented by a following formula (1), a compound (B2) represented by a following formula (2), a compound (B3) represented by a following formula (3), a compound (B4) represented by a following formula (4), and a compound (B5) represented by a following formula (5): 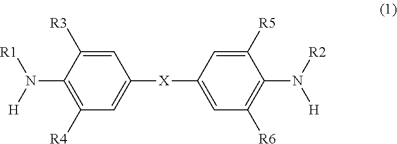
in the formula (1), R1 and R2 each independently represent a hydrogen atom or an alkyl group having 1 to 5 carbon atoms, R3 to R6 each independently represent a hydrogen atom or an alkyl group having 1 to 3 carbon atoms, and X represents —CH₂—, an oxygen atom, —SO₂—, or —C(CF₃)₂—; 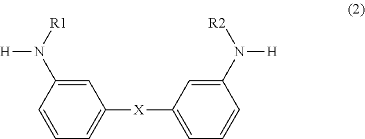
in the formula (2), R1 and R2 each independently represent a hydrogen atom or an alkyl group having 1 to 5 carbon atoms, and X represents —C(CH₃)₂— or an oxygen atom; 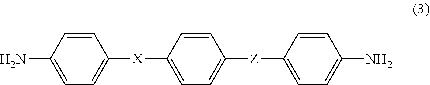
in the formula (3), X represents —C(CH₃)₂— or an oxygen atom, and Z represents —C(CH₃)₂— or an oxygen atom; 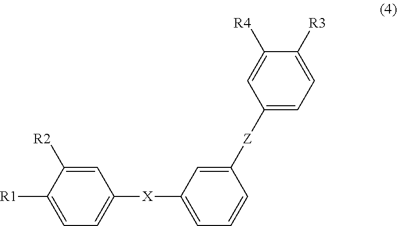
in the formula (4), one of R1 and R2 represents —NH₂ and another of R1 and R2 represents a hydrogen atom, one of R3 and R4 represents —NH₂ and another of R3 and R4 represents a hydrogen atom, X represents —C(CH₃)₂— or an oxygen atom, and Z represents —C(CH₃)₂— or an oxygen atom; and 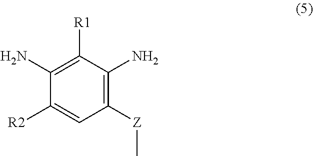
in the formula (5), R1 represents a methyl group or an ethyl group, R2 represents a methyl group, an ethyl group, or —SCH₃, and Z represents —CH₂— or a sulfur atom.

2. The reinforcing resin composition according to claim 1, wherein:
a proportion of the epoxy compound (A) is 48 mass % or more and 85 mass % or less in a solid content of the reinforcing resin composition, and
a proportion of the amine compound (B) is 5 mass % or more and 38 mass % or less in a solid content of the reinforcing resin composition.

3. The reinforcing resin composition according to claim 1, wherein the epoxy compound (A) includes an epoxy compound (A1) including at least one selected from the group consisting of a naphthalene epoxy resin, a biphenyl aralkyl epoxy resin, a trisphenol methane epoxy resin, a biphenyl epoxy resin, and a dicyclopentadiene epoxy resin.

4. The reinforcing resin composition according to claim 3, wherein a proportion of the epoxy compound (A1) is 16 mass % or more and 35 mass % or less in a solid content of the reinforcing resin composition.

5. The reinforcing resin composition according to claim 1, further comprising an activator (C).

6. The reinforcing resin composition according to claim 5, wherein a proportion of the activator (C) is 1.5 mass % or more and 25 mass % or less in a solid content of the reinforcing resin composition.

7. The reinforcing resin composition according to claim 1, further comprising a thixotropic agent (D).

8. The reinforcing resin composition according to claim 7, wherein a proportion of the thixotropic agent (D) is 1 mass % or more and 7 mass % or less in a solid content of the reinforcing resin composition.

9. The reinforcing resin composition according to claim 1, wherein a cured product of the reinforcing resin composition has a glass transition temperature of 100° C. or higher.

10. A mounted structure comprising:
a base material including a first conductor;
a mounted component having a second conductor;
a solder bump disposed between the first conductor and the second conductor, the solder bump electrically connecting the first conductor to the second conductor; and
a reinforcing part including a cured product of the reinforcing resin composition according to claim 1,
wherein the reinforcing part covers at least one of a joint between the first conductor and the solder bump or a joint between the second conductor and the solder bump.
